(19) United States
(12) Patent Application Publication
(10) Pub. No.: US 2008/0057598 A1
(43) Pub. Date: Mar. 6, 2008

(54) METHOD FOR FORMING FERROELECTRIC CAPACITOR AND METHOD FOR FABRICATING SEMICONDUCTOR DEVICE

(75) Inventors: Kenkichi SUEZAWA, Kawasaki (JP); Mitsushi FUJIKI, Kawasaki (JP); Makoto TAKAHASHI, Kawasaki (JP); Ko NAKAMURA, Kawasaki (JP); Wensheng WANG, Kawasaki (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: FUJITSU LIMITED, Kawasaki-shi (JP)

(21) Appl. No.: 11/847,717

(22) Filed: Aug. 30, 2007

(30) Foreign Application Priority Data
Aug. 31, 2006 (JP) 2006-234945

(51) Int. Cl. H01L 21/02

(52) U.S. Cl. 438/3; 257/E21.008

(57) ABSTRACT

A ferroelectric capacitor formation method that enables stable FeRAM mass production. When a ferroelectric capacitor of an FeRAM is formed, a ferroelectric layer is formed over a lower electrode layer by a sputtering method by keeping a stage at a temperature lower than or equal to 35° C. To crystallize the ferroelectric layer, first RTA treatment is performed in an atmosphere of a mixed gas which contains an inert gas and O₂ gas a concentration of which is 1.25 volume percent or greater. The formation of an upper electrode layer, second RTA treatment, patterning, and the like are then performed to form the ferroelectric capacitor. By doing so, ferroelectric capacitors each having predetermined capacitor performance can be formed with a high yield and FeRAMs can stably be mass-produced.

### CROSS-REFERENCE TO RELATED APPLICATIONS

This application is based upon and claims the benefits of priority from the prior Japanese Patent Application No. 2006-234945, filed on Aug. 31, 2006, the entire contents of which are incorporated herein by reference.

### BACKGROUND

(1) Field

This embodiment relates to a method for forming a ferroelectric capacitor and a method for fabricating a semiconductor device and, more particularly, to a method for forming a ferroelectric capacitor in which lead zirconate titanate (Pb(Zr,Ti)O₃), or PZT, is used for forming a ferroelectric layer and a method for fabricating a semiconductor device including such a ferroelectric capacitor.

(2) Description of the Related Art

A ferroelectric random access memory (FeRAM) includes memory cells each having a switching transistor and a ferroelectric capacitor. The ferroelectric capacitor has a structure in which a ferroelectric layer is located between a lower electrode layer and an upper electrode layer. Currently, PZT is widely used for forming such a ferroelectric layer. Conventionally, various methods for forming a ferroelectric capacitor in which a PZT layer is used have been proposed (see, for example, Japanese Patent Laid-Open Publication No. Hei03-019373, Japanese Patent No. 3,663,575, Japanese Patent Laid-Open Publication Nos. 2001-126955, 2002-246564, and 2004-153019).

### SUMMARY

The present embodiment was made under the background circumstances described above. An object of the present embodiment is to provide a ferroelectric capacitor formation method by which ferroelectric capacitors each having predetermined capacitor performance can stably be formed with a high yield.

Other systems, method, features and advantages of the invention will be or will become apparent to one with skill in the art upon examination of the following figures and detailed description. It is intended that all such additional systems, methods, features and advantages be included within this description, be within the scope of the invention, and be protected by the accompanying claims.

### BRIEF DESCRIPTION OF THE DRAWINGS

FIG. 1 shows an example of a process for fabricating an FeRAM.

FIG. 2 is a schematic sectional view showing an important part of an example of an FeRAM.

FIG. 3 shows the relationship between stage temperature at the time of depositing a PZT layer and the (222) orientation ratio of the PZT layer.

FIG. 4 shows the relationship between stage temperature at the time of depositing the PZT layer and the (101) orientation intensity of the PZT layer.

FIG. 5 shows the relationships between stage temperature at the time of depositing the PZT layer, the production yield of FeRAMs, and the incidence of a defect in retention.

FIG. 6 shows results obtained by measuring the (101) orientation intensity of the PZT layer while changing stage temperature at the time of depositing the PZT layer and O₂ gas concentration at the time of performing first RTA treatment.

FIG. 7 shows the relationship between stage temperature at the time of depositing the PZT layer and the (101) orientation ratio of the PZT layer.

FIG. 8 shows the relationship between process variations at the time of manufacturing 0.35-micron FeRAMs including memory cells of the 1T1C type and the number of nondefective products.

### DESCRIPTION OF THE PREFERRED EMBODIMENTS

With an FeRAM including ferroelectric capacitors in each of which a PZT layer is used, control over crystal orientation of the PZT layer which is directly related to a polarization inversion characteristic is very important. Conventionally, crystal orientation of a PZT layer has been controlled mainly by optimizing conditions concerning annealing temperature at the time of crystallizing PZT in an amorphous state deposited by a sputtering method or by optimizing a material or conditions for forming a lower electrode layer which is formed under the PZT layer and which influences crystal orientation of the PZT layer.

By the way, memory cells included in FeRAMs are of two types: a 1T1C type and a 2T2C type. A memory cell of the 1T1C type includes one transistor (T) and one ferroelectric capacitor (C). With a memory cell of the 2T2C type, two memory cells of the 1T1C type are combined and pieces of data held in these memory cells are opposite to each other. A circuit margin of a memory cell of the 1T1C type is small compared with a memory cell of the 2T2C type. With a memory cell of the 1T1C type, however, cell size can be reduced and the advantage of being able to realize device miniaturization and an increase in memory capacity is found. FeRAMs (0.35-micron FeRAMs) which include memory cells of the 1T1C type and in which a 0.35-micron design rule is adopted are now being manufactured.

However, when 0.35-micron FeRAMs including memory cells of the 1T1C type are manufactured, a defect in retention (data hold characteristic) tends to occur compared with FeRAMs including memory cells of the 2T2C type. As a result, the production yield tends to drop. The reason for this is as follows. As state above, a circuit margin of a memory cell of the 1T1C type is small compared with a memory cell of the 2T2C type. In addition, required specifications for a PZT layer itself have become more rigid with the years and permissible process variation at the time of manufacture has become smaller.

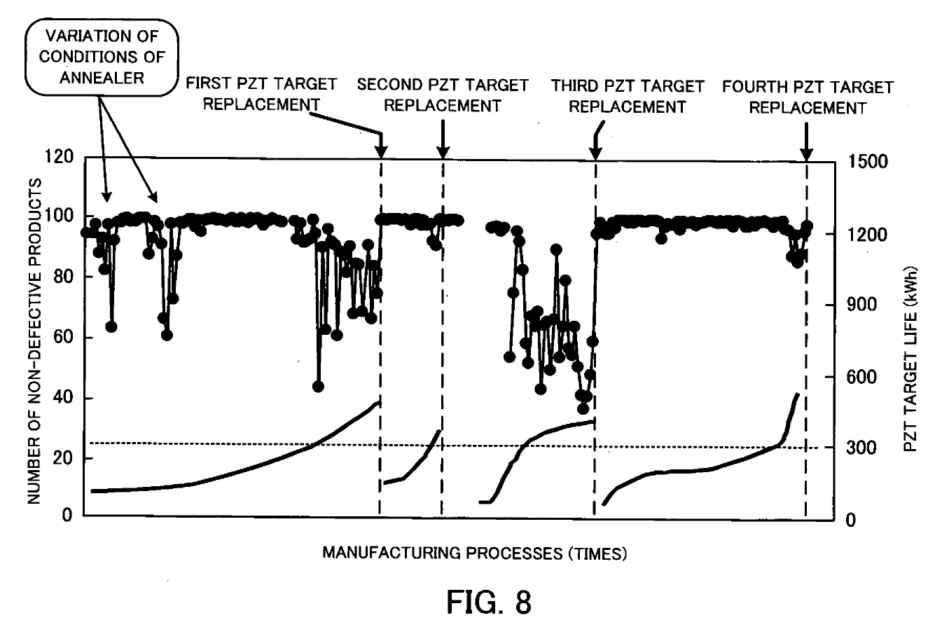

FIG. 8 shows the relationship between process variations at the time of manufacturing 0.35-micron FeRAMs including memory cells of the 1T1C type and the number of nondefective products.

In this case, each 0.35-micron FeRAM including memory cells of the 1T1C type is manufactured in the following way. A predetermined lower electrode layer is formed first over a substrate over which a predetermined transistor is formed with an insulating layer between. A PZT layer is formed over the lower electrode layer by the sputtering method. Annealing treatment is performed to crystallize the PZT layer. A predetermined upper electrode layer is formed over the PZT layer. Patterning is then performed on the upper electrode layer, the PZT layer, and the lower electrode layer and predetermined multilayer wirings are formed. FIG. 8 shows the situation of process variations and a situation in which a defect in retention occurs at the time of performing the above manufacturing process two or more times.

In FIG. 8, each dot indicates the number of nondefective products obtained at the time of performing a retention test on the same number of FeRAMs formed on a substrate in each manufacturing process. In FIG. 8, each curve indicates a value (kWh) (by which a PZT target life is indicated) obtained by adding up electric power supplied to a PZT target at sputtering time in two or more manufacturing processes before the PZT target is replaced.

As can be seen from FIG. 8, the number of nondefective products falls at a comparatively early stage of a series of FeRAM manufacturing processes before the first PZT target replacement. The timing of this fall matches the timing at which variations in the power of an annealer used for crystallizing a PZT layer after sputtering and temperature variations caused by the variations in the power of the annealer occurred. In several manufacturing processes after that, the number of nondefective products stabilizes at a great value. However, the number of nondefective products is showing a tendency to drop again. After first PZT target replacement is performed at this stage, the number of nondefective products stabilizes at a great value. After second PZT target replacement is performed, the number of nondefective products stabilizes at a great value in several manufacturing processes. After that, however, the number of nondefective products becomes unstable. After third PZT target replacement is performed, the number of nondefective products stabilizes again at a great value. When the above change in the number of nondefective products is compared with the PZT target life, it turns out that when the PZT target life exceeds about 300 kWh (indicated by dashed lines in FIG. 8), the number of nondefective products tends to become unstable.

As stated above, with 0.35-micron FeRAMs including memory cells of the 1T1C type the number of nondefective products which pass the retention test is significantly influenced by the variations in the power of the annealer used for crystallizing the PZT layer after the sputtering, the temperature variations caused by the variations in the power of the annealer, and the PZT target life at sputtering time. The orientation of all or part of crystals included in the PZT layer finally obtained differs from target orientation because of the process variations and the PZT target life and all or part of memory cells included in an FeRAM include such PZT layers. As a result, a defect in retention occurs in the FeRAM and the production yield drops.

A defect in retention which occurs by the above causes can be improved to a certain degree by rigidly managing the state of the annealer and the PZT target or by properly controlling conditions under which crystallization annealing and the sputtering are performed. However, retention is highly sensitive to the annealer and the PZT target life. Therefore, it is difficult to further improve a defect in retention only by managing the annealer and the PZT target life.

The present embodiment was made under the background circumstances described above. An object of the present embodiment is to provide a ferroelectric capacitor formation method by which ferroelectric capacitors each having predetermined capacitor performance can stably be formed with a high yield.

Another object of the present embodiment is to provide a method for fabricating a semiconductor device including a ferroelectric capacitor formed in such a way.

In order to achieve the above first object, a method for forming a ferroelectric capacitor in which a ferroelectric material is used for forming a dielectric layer is provided. This method comprises the steps of forming a lower electrode layer having a laminated structure including an aluminum oxide film and a platinum film over an insulating layer formed over a substrate, forming a ferroelectric layer of lead zirconate titanate over the lower electrode layer by a sputtering method by keeping a stage on which the substrate is placed at a temperature lower than or equal to 35° C., performing first rapid thermal annealing treatment in an atmosphere of a mixed gas which contains an inert gas and oxygen gas a concentration of which is 1.25 volume percent or greater after the formation of the ferroelectric layer, forming a first upper electrode layer of iridium oxide over the ferroelectric layer after the first rapid thermal annealing treatment, performing second rapid thermal annealing treatment after the formation of the first upper electrode layer, forming a second upper electrode layer of iridium oxide over the first upper electrode layer after the second rapid thermal annealing treatment, and performing patterning on the first upper electrode layer, the second upper electrode layer, the ferroelectric layer, and the lower electrode layer after the formation of the second upper electrode layer.

In addition, in order to achieve the above second object, a method for fabricating a semiconductor device including a ferroelectric capacitor is provided. This method comprises the steps of forming a lower electrode layer having a laminated structure including an aluminum oxide film and a platinum film over an insulating layer formed over a substrate on which a transistor is formed, forming a ferroelectric layer of lead zirconate titanate over the lower electrode layer by a sputtering method by keeping a stage on which the substrate is placed at a temperature lower than or equal to 35° C., performing first rapid thermal annealing treatment in an atmosphere of a mixed gas which contains an inert gas and oxygen gas a concentration of which is 1.25 volume percent or greater after the formation of the ferroelectric layer, forming a first upper electrode layer of iridium oxide over the ferroelectric layer after the first rapid thermal annealing treatment, performing second rapid thermal annealing treatment after the formation of the first upper electrode layer, forming a second upper electrode layer of iridium oxide over the first upper electrode layer after the second rapid thermal annealing treatment, and performing patterning on the first upper electrode layer, the second upper electrode layer, the ferroelectric layer, and the lower electrode layer after the formation of the second upper electrode layer for forming the ferroelectric capacitor.

The above and other objects, features and advantages of the present embodiment will become apparent from the following description when taken in conjunction with the accompanying drawings which illustrate preferred embodiments by way of example.

Embodiments will now be described in detail with reference to the drawings.

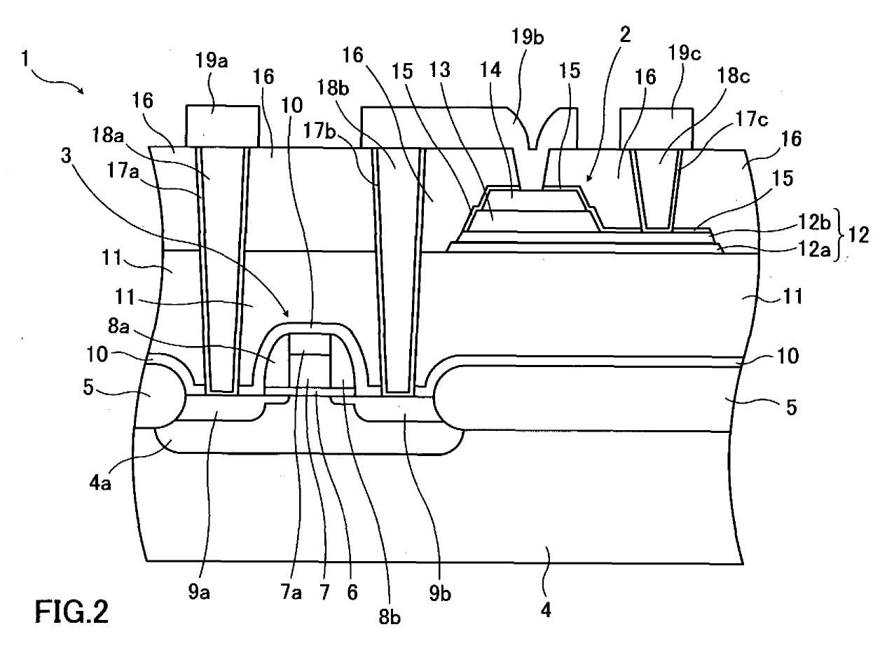

FIG. 2 is a schematic sectional view showing an important part of an example of an FeRAM. In FIG. 2, only a memory cell region of an FeRAM including a memory cell of the 1T1C type is shown and the other circuit region around the memory cell region is not shown.

An FeRAM 1 includes a ferroelectric capacitor 2 for holding data and a metal oxide semiconductor (MOS) transistor 3 for accessing the data.

The MOS transistor 3 is formed in, for example, a p-type well 4a defined in, for example, a p-type silicon (Si) substrate 4 by isolation regions 5 formed of a field oxide film or the like. A gate electrode 7 which functions as a word line of the FeRAM 1 is formed over the Si substrate 4 with a gate insulating film 6 between. A silicide layer 7a of tungsten (W) silicide or the like is formed in a surface portion of the gate electrode 7. Sidewall insulating films 8a and 8b of silicon oxide (SiO₂) or the like are formed on both sides of the gate electrode 7. For example, n-type impurity diffusion regions 9a and 9b each having a lightly doped drain (LDD) structure are formed in the Si substrate 4 on both sides of the gate electrode 7. As a result, for example, the n-channel MOS transistor 3 is formed.

The MOS transistor 3 having the above structure is covered with a cover film 10 of, for example, silicon oxide nitride (SiON). A first interlayer dielectric film 11 of, for example, SiO₂ is formed over the cover film 10. The ferroelectric capacitor 2 is formed over the first interlayer dielectric film 11.

The ferroelectric capacitor 2 includes a lower electrode layer 12, a ferroelectric layer 13, and an upper electrode layer 14 formed in tiers. The lower electrode layer 12 has a laminated structure in which a platinum (Pt) film 12b is formed over an aluminum oxide (Al₂O₃) film 12a. The lower electrode layer 12 may be an iridium (Ir) film, a ruthenium (Ru) film, or a conductive oxide film such as a ruthenium oxide (RuO₂) film or a strontium ruthenate (SrRuO₃) film, or have a laminated structure in which two of these films are formed properly. However, if morphology, productivity, and the like are taken into consideration, it is desirable that the lower electrode layer 12 should have a laminated structure including the Al₂O₃ film 12a and the Pt film 12b. The ferroelectric layer 13 is formed of PZT. The upper electrode layer 14 is formed of iridium oxide (IrOₓ).

A capacitor protection insulating film 15 of Al₂O₃, PZT, silicon nitride (SiN), SiON, or the like is formed over the ferroelectric capacitor 2. A second interlayer dielectric film 16 of, for example, SiO₂ is formed over the capacitor protection insulating film 15 and the first interlayer dielectric film 11.

Glue films 17a and 17b of titanium (Ti), titanium nitride (TiN), and the like and conductive plugs 18a and 18b of, for example, tungsten (W) are formed in contact holes which pierce the second interlayer dielectric film 16, the first interlayer dielectric film 11, and the cover film 10. The glue film 17a and the conductive plug 18a are electrically connected to the impurity diffusion region 9a of the MOS transistor 3. Similarly, the glue film 17b and the conductive plug 18b are electrically connected to the impurity diffusion region 9b of the MOS transistor 3. In addition, a glue film 17c of Ti, TiN, and the like and a conductive plug 18c of, for example, W formed in a contact hole which pierces the second interlayer dielectric film 16 are electrically connected to the lower electrode layer 12 of the ferroelectric capacitor 2.

A wiring layer 19a having a laminated structure in which TiN, aluminum (Al), Ti, TiN, for example, are formed in order is formed over the glue film 17a and the conductive plug 18a. Similarly, a wiring layer 19b having a laminated structure in which TiN, Al, Ti, TiN are formed in order is formed over the glue film 17b and the conductive plug 18b. A wiring layer 19c having a laminated structure in which TiN, Al, Ti, TiN are formed in order is formed over the glue film 17c and the conductive plug 18c. The wiring layer 19b electrically connected to the impurity diffusion region 9b of the MOS transistor 3 is electrically connected to the upper electrode layer 14 of the ferroelectric capacitor 2 via a contact hole which pierces the second interlayer dielectric film 16.

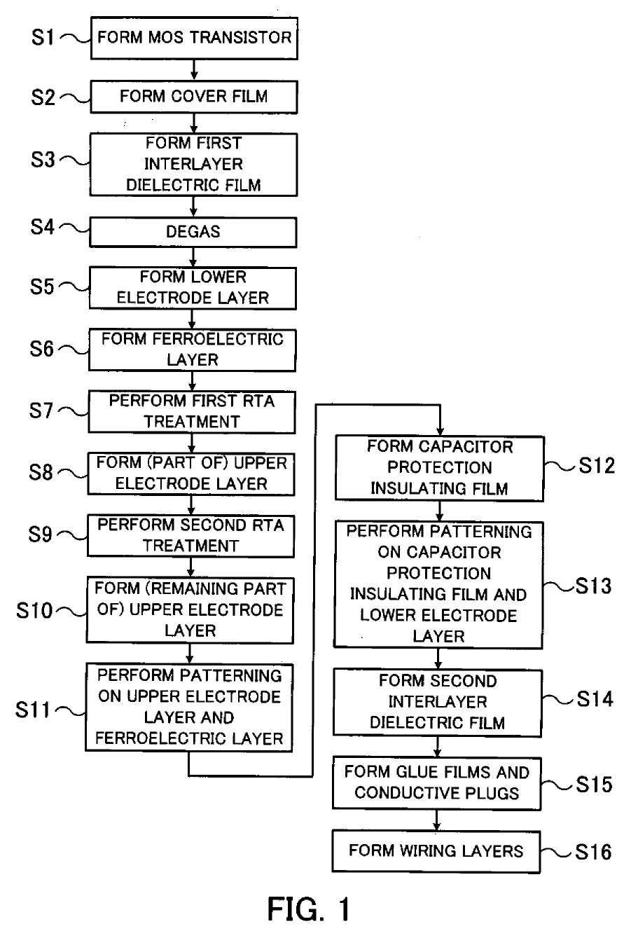

The FeRAM 1 having the above structure can be fabricated by, for example, a process shown in FIG. 1.

FIG. 1 shows an example of a process for fabricating an FeRAM.

The well 4a, the gate insulating film 6, the gate electrode 7, the silicide layer 7a, the sidewall insulating films 8a and 8b, and the impurity diffusion regions 9a and 9b are formed first in an element region defined by the isolation regions 5 according to an ordinary method to form the MOS transistor 3 (step S1).

SiON, for example, is then deposited over the substrate on which the MOS transistor 3 is formed by a chemical vapor deposition (CVD) method to form the cover film 10 (step S2).

An SiO₂ film with a thickness of about 1,000 nm is then deposited over the cover film 10 by the CVD method in which TEOS gas is used. The SiO₂ film is planarized by a chemical mechanical polishing (CMP) method to form the first interlayer dielectric film 11 (step S3).

Annealing is then performed in an atmosphere of nitrogen (N₂) at a temperature of about 650° C. for about 30 minutes to perform degassing (step S4).

The Al₂O₃ film 12a and the Pt film 12b are then deposited in that order over the entire surface of the first interlayer dielectric film 11 after the degassing to form the lower electrode layer 12 (step S5).

The Al₂O₃ film 12a included in the lower electrode layer 12 is deposited over the first interlayer dielectric film 11 by a DC sputtering method. The thickness of the Al₂O₃ film 12a is between 5 and 100 nm and is set to, for example, about 20 nm. The Al₂O₃ film 12a formed in this way is in an amorphous state.

The Pt film 12b included in the lower electrode layer 12 is deposited on the Al₂O₃ film 12a by the DC sputtering method. The thickness of the Pt film 12b is between 50 and 300 nm and is set to, for example, about 155 nm. The Pt film 12b is formed under conditions under which the (111) plane is preferentially oriented.

By depositing the Al₂O₃ film 12a and the Pt film 12b in order in this way, the lower electrode layer 12 is formed first over the entire surface of the first interlayer dielectric film 11.

A PZT layer (Pb/(Zr+Ti)=1.116−1.146) is then deposited over the lower electrode layer 12 formed by an RF sputtering method to form the ferroelectric layer 13 (step S6). The thickness of the PZT layer is between 100 and 300 nm and is set to, for example, about 150 nm. The PZT layer deposited is in an amorphous state.

In step S6 for forming the ferroelectric layer 13, the temperature of a stage on which the substrate is placed is set to 20 to 80° C. Preferably, the temperature of the stage on which the substrate is placed is set to 20 to 35° C. By depositing the PZT layer at this stage temperature, control can be exercised so as to orient crystals included in the PZT layer finally obtained in a predetermined direction. The relationship between stage temperature at the time of depositing the PZT layer and the crystal orientation of the PZT layer will be described later.

To crystallize the deposited PZT layer in an amorphous state, first rapid thermal anneal (RTA) treatment (first RTA treatment) is then performed by using a lamp annealer or the like (step S7).

The first RTA treatment is performed in an atmosphere of a mixed gas which contains oxygen (O₂) gas at predetermined partial pressure and argon (Ar) gas at predetermined partial pressure at a temperature between 500 and 600° C. (about 563° C., for example) for about 90 seconds. The PZT layer in an amorphous state can be crystallized by setting O₂ gas concentration in the mixed gas used in the first RTA treatment to 0.1 to 50 volume percent. However, to obtain the ferroelectric capacitor 2 in which a switching electric charge amount Q_{sw} is larger than or equal to a certain value, it is preferable that O₂ gas concentration at the time of performing the first RTA treatment should be set to about 1 to 5 volume percent.

In the first RTA treatment performed in step S7, the O₂ gas concentration at the time of the first RTA treatment significantly influences the crystal orientation of the PZT layer finally obtained. Therefore, the O₂ gas concentration is controlled so that predetermined orientation will preferentially be obtained. The relationship between the O₂ gas concentration at the time of the first RTA treatment and stage temperature at the time of depositing the PZT layer which also influences the crystal orientation of the PZT layer will be described later.

An IrOₓ film with a thickness of about 50 nm which is part of the upper electrode layer 14 (first upper electrode layer) is then deposited by the DC sputtering method over the entire surface of the ferroelectric layer 13 after the first RTA treatment (step S8).

A second RTA treatment (second RTA treatment) is then performed in an atmosphere of O₂—Ar mixed gas (in which O₂ gas concentration is about 1 volume percent and Ar gas concentration is about 99 volume percent) at a temperature of about 708° C. for about 20 seconds (step S9).

An IrOₓ film with a thickness of about 200 nm is then deposited over the entire surface of the part of the upper electrode layer 14 previously formed in step S8. By doing so, the remaining part of the upper electrode layer 14 (second upper electrode layer) is formed to obtain an IrOₓ film which includes the IrOₓ film deposited in step S8 and the thickness of which is about 250 nm (step S10). The second upper electrode layer may be formed so that the oxidation degree of the IrOₓ film which is the first upper electrode layer will be lower than that of the IrOₓ film which is the second upper electrode layer. Accordingly, the value of the composition parameter x of the IrOₓ film which is the first upper electrode layer does not always match the value of the composition parameter x of the IrOₓ film which is the second upper electrode layer.

Patterning is performed on the upper electrode layer 14 and the ferroelectric layer 13 in order to form predetermined shapes (step S11). When patterning is performed on the ferroelectric layer 13 after patterning is performed on the upper electrode layer 14, the ferroelectric layer 13 should be left not only just under the upper electrode layer 14 but also around the upper electrode layer 14.

An Al₂O₃ film, a PZT film, an SiN film, an SiON film, or the like with a thickness of 20 to 50 nm is then deposited over an entire surface by a sputtering method to form the capacitor protection insulating film 15 (step S12).

Patterning is then performed on the capacitor protection insulating film 15 and the lower electrode layer 12 to form predetermined shapes (step S13). As a result, the ferroelectric capacitor 2 having a laminated structure including the lower electrode layer 12, the ferroelectric layer 13, and the upper electrode layer 14 is formed.

The second interlayer dielectric film 16 is then formed over an entire surface (step S14). For example, the second interlayer dielectric film 16 is formed in the following way. An SiO₂ film with a thickness of about 1,000 nm is deposited first by the CVD method in which TEOS gas is used. The CMP method is then used for making the final thickness of the SiO₂ film about 300 nm.

The contact holes which lead to the impurity diffusion regions 9a and 9b and the lower electrode layer 12 are then formed. For example, after a Ti film with a thickness of about 20 nm and a TiN film with a thickness of about 50 nm are formed in the contact holes by the sputtering method, a W film is embedded in the contact holes by the CVD method. These films are removed to the level of the surface of the second interlayer dielectric film 16 by the CMP method to form the glue films 17a, 17b, and 17c and the conductive plugs 18a, 18b, and 18c in the contact holes (step S15).

The contact hole which leads to the upper electrode layer 14 is then formed. After that, a TiN film with a thickness of about 150 nm, an Al film with a thickness of about 500 nm, a Ti film with a thickness of about 5 nm, and a TiN film with a thickness of about 100 nm, for example, are deposited in order over an entire surface and patterning is performed on these films. By doing so, the wiring layers 19a, 19b, and 19c are formed (step S16).

By performing the above process, the FeRAM 1 having the structure shown in FIG. 2 is fabricated.

Stage temperature at the time of depositing the PZT layer in the above step S6 and O₂ gas concentration at the time of performing the first RTA treatment in the above step S7 will now be described in further detail.

The relationship between stage temperature at the time of depositing the PZT layer and the crystal orientation of the PZT layer will be described first.

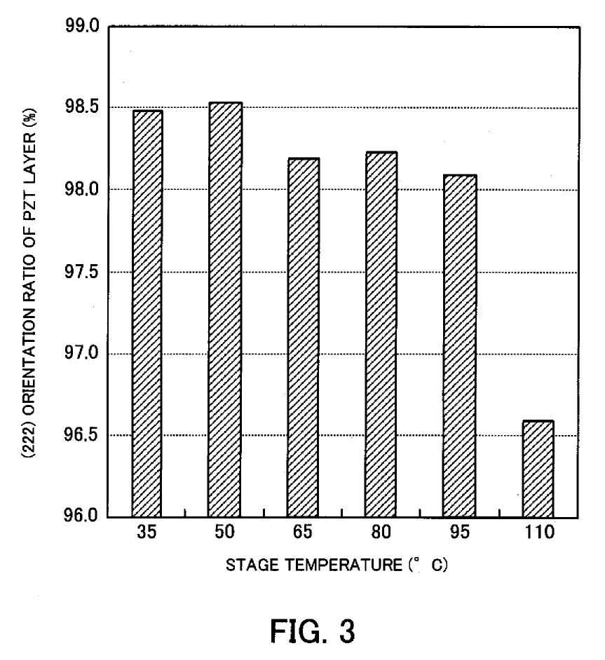

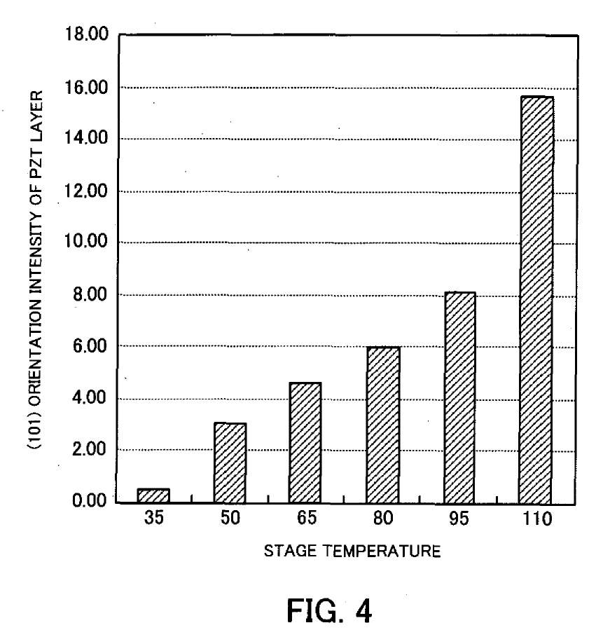

FIG. 3 shows the relationship between stage temperature at the time of depositing the PZT layer and the (222) orientation ratio of the PZT layer. FIG. 4 shows the relationship between stage temperature at the time of depositing the PZT layer and the (101) orientation intensity of the PZT layer.

The polarization value of the PZT layer is maximized when the PZT layer is oriented in the (001) direction. From the viewpoint of the productivity of the FeRAM 1, however, it is preferable that the PZT layer should preferentially be oriented in the (111) direction ((222) direction). The reason for this is that it is easier to orient the PZT layer in the (111) direction ((222) direction) and that because a switching direction forms an angle of 45° with an inverted electric field, a comparatively great polarization value can be obtained.

Accordingly, after the lower electrode layer was formed, the PZT layer was deposited at stage temperatures of 35, 50, 65, 80, 95, and 110° C., the first RTA treatment was performed, the part of the upper electrode layer was formed, and the second RTA treatment was performed. The crystal orientation of the PZT layer was then evaluated. The crystal orientation of the PZT layer was evaluated by the (222) orientation ratio of the PZT layer calculated by using the integrated intensity of each diffraction peak measured by utilizing X-ray diffraction (XRD). Results obtained by calculating the (222) orientation ratio of the PZT layer are shown in FIG. 3. The (101) orientation intensity (integrated intensity) of the PZT layer which contributes to a decrease in the polarization value obtained by the (222) plane of the PZT layer is shown in FIG. 4. When samples used for evaluating the crystal orientation of the PZT layer were fabricated, stage temperature at the time of depositing the PZT layer was changed in the above way. However, the other conditions, that is to say, conditions under which the formation of the lower electrode layer, the first RTA treatment, the formation of the part of the upper electrode layer, and the second RTA treatment were performed were the same.

As can be seen from FIG. 3, the (222) orientation ratio of the PZT layer is showing a tendency to decrease with a rise in stage temperature at the time of depositing the PZT layer. Furthermore, as can be seen from FIG. 4, the (101) orientation intensity of the PZT layer is showing a tendency to increase with a rise in stage temperature at the time of depositing the PZT layer. From FIGS. 3 and 4, it may safely be said that by keeping stage temperature at the time of depositing the PZT layer rather low, the generation of the (101) plane of the PZT layer can be suppressed at the time of crystallizing the PZT layer.

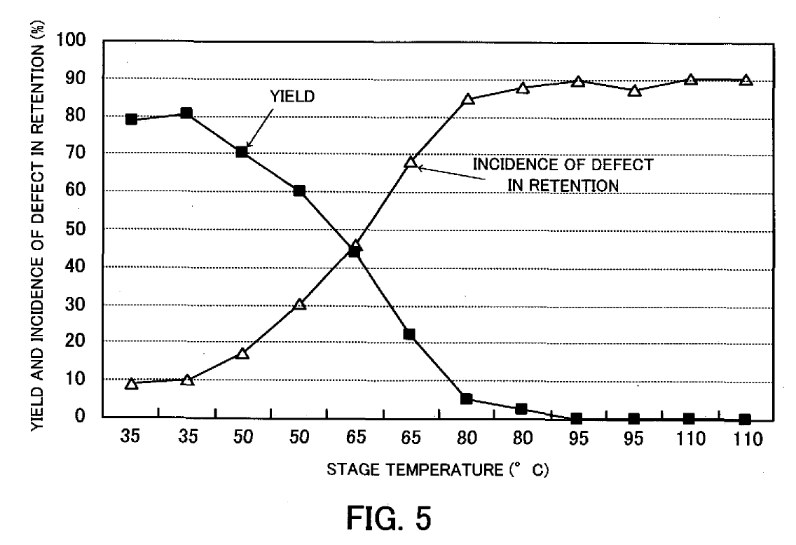

Results obtained by examining the influence of stage temperature at the time of depositing the PZT layer which influences the crystal orientation of the PZT layer on the production yield of FeRAMs and retention are shown in FIG. 5.

FIG. 5 shows the relationships between stage temperature at the time of depositing the PZT layer, the production yield of FeRAMs, and the incidence of a defect in retention.

In this case, FeRAMs used for evaluating the production yield and the retention were fabricated according to the process shown in FIG. 1. In the FeRAMs, however, the PZT layers were deposited at different stage temperatures, that is to say, at stage temperatures of 35, 50, 65, 80, 95, and 110° C. When the PZT layers were deposited at each stage temperature, a PZT target which was nearing the limitation of use, that is to say, which was in the last stage of the life (PZT target life is about 300 kWh) was used. When these FeRAMs were fabricated, the PZT layers were deposited at the different stage temperatures. However, the other conditions were the same.

As can be seen from FIG. 5, the production yield of the FeRAMs is showing a tendency to drop with a rise in stage temperature at the time of depositing the PZT layer. The incidence of a defect in retention is showing a tendency to increase with a rise in stage temperature at the time of depositing the PZT layer. That is to say, when stage temperature at the time of depositing the PZT layer is high, a defect in retention tends to occur. As a result, the production yield of the FeRAMs drops.

As shown in FIGS. 3 through 5, by keeping stage temperature at the time of depositing the PZT layer rather low, the generation of the (101) plane of the PZT layer can be suppressed and the (111) orientation ratio of the PZT layer can be raised. Accordingly, many ferroelectric capacitors each having predetermined performance can be formed more homogeneously. As a result, the occurrence of a defect in retention can be suppressed and the production yield of FeRAMs can be improved.

The relationship between stage temperature at the time of depositing the PZT layer and O₂ gas concentration at the time of performing the first RTA treatment will now be described.

The incidence of a defect in retention is influenced not only by stage temperature at the time of depositing the PZT layer but also by conditions under which the first RTA treatment is performed after the deposition of the PZT layer. The incidence of a defect in retention is strongly influenced especially by O₂ gas concentration at the time of performing the first RTA treatment.

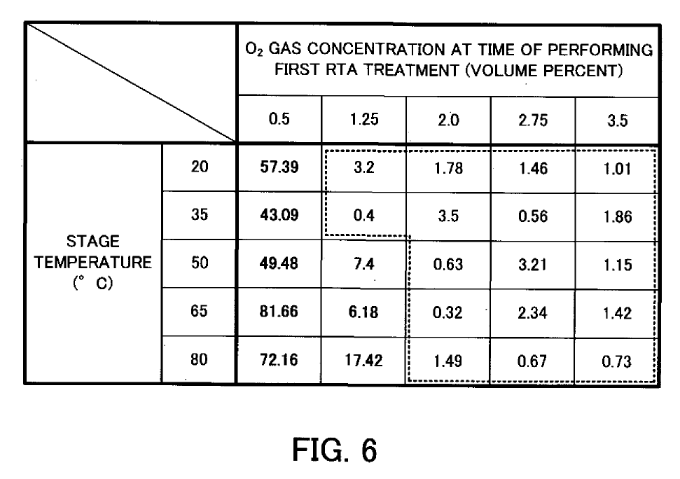

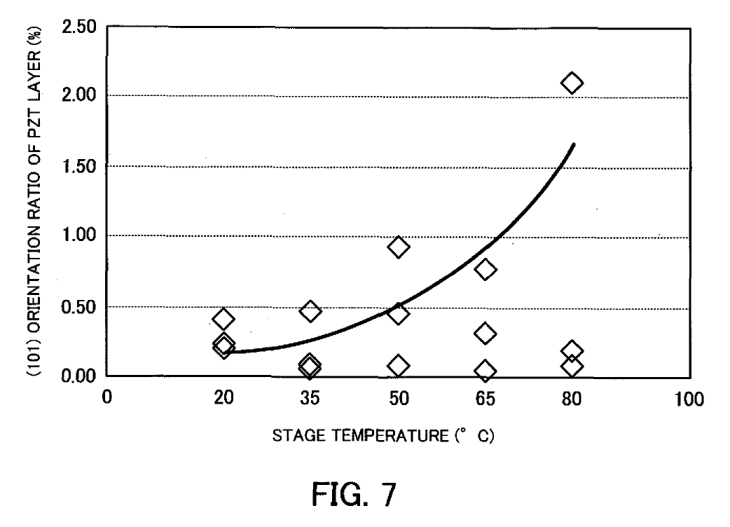

FIG. 6 shows results obtained by measuring the (101) orientation intensity of the PZT layer while changing stage temperature at the time of depositing the PZT layer and O₂ gas concentration at the time of performing the first RTA treatment. FIG. 7 shows the relationship between stage temperature at the time of depositing the PZT layer and the (101) orientation ratio of the PZT layer.

As stated above, the (101) plane of the PZT layer contributes to a decrease in the polarization value obtained by the (111) plane of the PZT layer. Therefore, to suppress the occurrence of a defect in retention and improve the production yield of FeRAMs, it is desirable that the generation of the (101) plane of the PZT layer should be suppressed.

In FIG. 6, stage temperature at the time of depositing the PZT layer after the formation of the lower electrode layer is set to 20, 35, 50, 65, and 80° C. O₂ gas concentration (total flow rate of O₂ gas and Ar gas is 2,000 scam (1 sccm=1 ml/min (at 0° C. and 101.3 kPa))) at the time of performing the first RTA treatment on the PZT layer deposited at each stage temperature is set to 0.5 volume percent (10 sccm), 1.25 volume percent (25 sccm), 2.0 volume percent (40 sccm), 2.75 volume percent (55 sccm), and 3.5 volume percent (70 sccm). The first RTA treatment is performed at a temperature of about 563° C. for 90 seconds. After that, the part of the upper electrode layer is formed, the second RTA treatment is performed, and the (161) orientation intensity and orientation ratio of the PZT layer are determined by using XRD. When samples were fabricated, stage temperature at the time of depositing the PZT layer and O₂ gas concentration at the time of performing the first RTA treatment were changed. However, the other conditions, that is to say, conditions under which the formation of the lower electrode layer, the temperature and time in the first RTA treatment, the formation of the part of the upper electrode layer, and the second RTA treatment were performed were the same.

If the (101) orientation intensity of the PZT layer obtained after the first RTA treatment is at a level in a frame of a dotted line shown in FIG. 6, then the possibility that a defect in retention occurs can be made small.

As can be seen from FIG. 6, when O₂ gas concentration at the time of performing the first RTA treatment is higher than or equal to 2.0 volume percent (40 sccm) and stage temperature at the time of the deposition of the PZT layer performed before the first RTA treatment is raised to 80° C., the generation of the (101) plane of the PZT layer is effectively suppressed.

When O₂ gas concentration at the time of performing the first RTA treatment is 1.25 volume percent (25 sccm) and stage temperature at the time of depositing the PZT layer is lower than or equal to 35° C., the generation of the (101) plane of the PZT layer is effectively suppressed. However, when stage temperature at the time of depositing the PZT layer is higher than or equal to 50° C., the generation of the (101) plane of the PZT layer is recognized more clearly.

When O₂ gas concentration at the time of performing the first RTA treatment is 0.5 volume percent (10 sccm) and stage temperature at the time of depositing the PZT layer is low, the effect of suppressing the generation of the (101) plane of the PZT layer is recognized. However, the generation of the (101) plane of the PZT layer cannot be suppressed to a low level.

A graph shown in FIG. 7 is obtained from the results shown in FIG. 6. That is to say, this graph shows the relationship between stage temperature at the time of depositing the PZT layer and the (101) orientation ratio of the PZT layer in the case of setting O₂ gas concentration to 1.25 volume percent (25 sccm), 2.0 volume percent (40 sccm), and 2.75 volume percent (55 sccm) at the time of the first RTA treatment.

As can be seen from FIG. 7, when stage temperature at the time of depositing the PZT layer is higher than or equal to 50° C., the generation ratio of the (101) plane of the PZT layer varies in a comparatively wide range. However, when stage temperature at the time of depositing the PZT layer is lower than or equal to 35° C., the generation of the (101) plane of the PZT layer is reliably suppressed. The same also applies to the case where the orientation ratio of the (101) plane of the PZT layer at each stage temperature which is obtained at an O₂ gas concentration of 3.5 volume percent (70 sccm) and which is shown in FIG. 6 is added to FIG. 7.

In other words, even if O₂ gas concentration at the time of the first RTA treatment varies in the range of, for example, 1.25 volume percent (25 sccm) to 2.75 volume percent (55 sccm) or in the wider range of 1.25 volume percent (25 sccm) to 3.5 volume percent (70 sccm) in the process for fabricating an FeRAM, stage temperature at the time of depositing the PZT layer prior to the first RTA treatment should be kept at a temperature lower than or equal to 35° C. By doing so, the generation of the (101) plane of the PZT layer is suppressed and the (111) orientation ratio of the PZT layer can be raised. As a result, the occurrence of a defect in retention can be suppressed and the production yield can be raised.

By keeping stage temperature at the time of depositing the PZT layer at a temperature lower than or equal to 35° C., a process margin can be widened and a stable process that can accommodate variation of conditions under which the first RTA treatment is performed can be established.

As a result, even if there is a difference in process margin among a plurality of annealers or sputtering systems used for mass-producing FeRAMs, it is easy to manage the state of these annealers or sputtering systems and to control conditions under which these annealers or sputtering systems are used. In addition, if production is increased or systems are added, FeRAMs each having predetermined performance can stably be mass-produced.

The technique of controlling stage temperature at the time of depositing the PZT layer is very effective for fabricating an FeRAM including memory cells of the 1T1C type. However, this technique is also applicable to the fabrication of an FeRAM including memory cells of the 2T2C type. Furthermore, this technique is applicable regardless of which design rule is adopted.

The descriptions have been given with the case where PZT is used for forming the ferroelectric layer of the ferroelectric capacitor as an example. However, even if PZT doped with lanthanum (La) is used in place of PZT, the above effect can be obtained by controlling stage temperature at the time of depositing a layer which contains PZT doped with La.

With the present embodiment, when the sputtering method is used for forming the ferroelectric layer of PZT, stage temperature is kept at a temperature lower than or equal to 35° C. In addition, when the first rapid thermal anneal treatment is performed after the formation of the ferroelectric layer, O₂ gas concentration in the mixed gas is set to 1.25 volume percent or greater. By doing so, the orientation ratio of the predetermined crystal plane of the ferroelectric layer finally obtained can be improved and ferroelectric capacitors each having predetermined capacitor performance can stably be produced with a high yield. Accordingly, semiconductor devices each including a ferroelectric capacitor can stably be mass-produced.

The foregoing is considered as illustrative only of the principles of the present embodiment. Furthers since numerous modifications and changes will readily occur to those skilled in the art, it is not desired to limit the invention to the exact construction and applications shown and described, and accordingly, all suitable modifications and equivalents may be regarded as falling within the scope of the invention in the appended claims and their equivalents.

What is claimed is:

1. A method for forming a ferroelectric capacitor in which a ferroelectric material is used for forming a dielectric layer, the method comprising the steps of:
forming a lower electrode layer having a laminated structure including an aluminum oxide film and a platinum film over an insulating layer formed over a substrate;
forming a ferroelectric layer of lead zirconate titanate over the lower electrode layer by a sputtering method by keeping a stage on which the substrate is placed at a temperature lower than or equal to 35° C.;
performing first rapid thermal annealing treatment in an atmosphere of a mixed gas which contains an inert gas and oxygen gas a concentration of which is 1.25 volume percent or greater after the formation of the ferroelectric layer;
forming a first upper electrode layer of iridium oxide over the ferroelectric layer after the first rapid thermal annealing treatment;
performing second rapid thermal annealing treatment after the formation of the first upper electrode layer;
forming a second upper electrode layer of iridium oxide over the first upper electrode layer after the second rapid thermal annealing treatment; and
performing patterning on the first upper electrode layer, the second upper electrode layer, the ferroelectric layer, and the lower electrode layer after the formation of the second upper electrode layer.

2. The method according to claim 1, wherein in the step of forming the ferroelectric layer over the lower electrode layer, the ferroelectric layer is formed over the lower electrode layer by keeping the stage at a temperature between 20 and 35° C.

3. The method according to claim 1, wherein in the step of performing the first rapid thermal annealing treatment, the first rapid thermal annealing treatment is performed in an atmosphere of the mixed gas which contains the inert gas and oxygen gas the concentration of which is between 1.25 and 3.5 volume percent.

4. The method according to claim 1, wherein an oxidation degree of the iridium oxide which is the first upper electrode layer is lower than an oxidation degree of the iridium oxide which is the second upper electrode layer.

5. The method according to claim 1, wherein in the step of performing the first rapid thermal annealing treatment, the first rapid thermal annealing treatment is performed at a temperature between 500 and 600° C.

6. A method for fabricating a semiconductor device including a ferroelectric capacitor, the method comprising the steps of:
forming a lower electrode layer having a laminated structure including an aluminum oxide film and a platinum film over an insulating layer formed over a substrate on which a transistor is formed;
forming a ferroelectric layer of lead zirconate titanate over the lower electrode layer by a sputtering method by keeping a stage on which the substrate is placed at a temperature lower than or equal to 35° C.;
performing first rapid thermal annealing treatment in an atmosphere of a mixed gas which contains an inert gas and oxygen gas a concentration of which is 1.25 volume percent or greater after the formation of the ferroelectric layer;
forming a first upper electrode layer of iridium oxide over the ferroelectric layer after the first rapid thermal annealing treatment;
performing second rapid thermal annealing treatment after the formation of the first upper electrode layer;
forming a second upper electrode layer of iridium oxide over the first upper electrode layer after the second rapid thermal annealing treatment; and
performing patterning on the first upper electrode layer, the second upper electrode layer, the ferroelectric layer, and the lower electrode layer after the formation of the second upper electrode layer for forming the ferroelectric capacitor.

7. The method according to claim 6, wherein in the step of forming the ferroelectric layer over the lower electrode layer, the ferroelectric layer is formed over the lower electrode layer by keeping the stage at a temperature between 20 and 35° C.

8. The method according to claim 6, wherein in the step of performing the first rapid thermal annealing treatment, the first rapid thermal annealing treatment is performed in an atmosphere of the mixed gas which contains the inert gas and oxygen gas the concentration of which is between 1.25 and 3.5 volume percent.

9. The method according to claim 6, wherein an oxidation degree of the iridium oxide which is the first upper electrode layer is lower than an oxidation degree of the iridium oxide which is the second upper electrode layer.

10. The method according to claim 6, wherein in the step of performing the first rapid thermal annealing treatment, the first rapid thermal annealing treatment is performed at a temperature between 500 and 600° C.
